(19) United States
(12) Patent Application Publication
(10) Pub. No.: US 2002/0079945 A1
(43) Pub. Date: Jun. 27, 2002

(54) Method and apparatus of isolating and level setting

(76) Inventors: Philip Wayne Johnson, Bluffton, IN (US); Glen Chester Young, Ft. Wayne, IN (US); Scott A. Coonrod, Ft. Wayne, IN (US); Brian L. Beifus, Ft. Wayne, IN (US); Steven A, Keller, Ft. Wayne, IN (US)

Correspondence Address: John S. Beulick, Armstrong Teasdale LLP, Suite 2600, One Metropolitan Sq., St. Louis, MO, 63102, US

(21) Appl. No.: 09/749,313

(22) Filed: Dec. 27, 2000

(51) Int. Cl. H03L 5/00

(52) U.S. Cl. 327/333

(57) ABSTRACT

An electrical isolation circuit that sets a voltage level for programming a product is contained in a stand-alone module. The electrical circuit includes a first input terminal connected to a first optocoupler, which provides a first level of isolation, a transformer, which provides a second level of isolation, and a second optocoupler, which provides a third level of isolation. The circuit outputs a signal to a level setting circuit prior to outputting the signal. An advantage of the module is it interfaces with a plurality of programming boxes, so new modules do not have to be created.

### BACKGROUND OF THE INVENTION

This invention relates generally to electronic module interfaces and, more particularly to electrical isolation circuits.

Electrical isolation circuits including level setting provide isolation between high voltage power and low voltage power lines. Such isolation circuits also isolate electrical circuits during hi-pot testing. In addition, isolation circuits set the correct voltage level for input pins programming a product, e.g., an electrically commutated motor.

Electrical isolation is an important consideration if the components of a system use different power sources, have noisy signals, or operate at different ground potentials. Isolation is needed to prevent the effects of ground currents. Therefore, isolation circuitry is necessary to ensure the correct noise-free, voltage level is applied to the input pins when a product is being programmed. If an incorrect or noisy voltage level is applied to the input pins of a product during programming, the product can be damaged or the resulting programming will be invalid.

It is desirable to use a stand-alone electrical isolation circuit that will interface between a product and a programming box. It is also desirable to have the electrical isolation circuitry contain an optically coupled isolator. Finally, it is desirable to have the isolation circuit work in series with existing, known programming boxes to create the correct voltage level or reduce noise during programming.

### BRIEF SUMMARY OF THE INVENTION

In an exemplary embodiment of the invention an electrical isolation circuit that sets a voltage level for programming a product is contained in a stand-alone module. The module contains input and output connectors to electrically couple the module to the product being programmed and interface to a programming box. An advantage of the module is that it interfaces with a plurality of programming boxes, so new modules do not have to be created for each specific programming box.

The electrical circuit includes, in one embodiment, a first input terminal connected to a first optocoupler, which provides a first level of isolation. The electrical circuit also includes an oscillator circuit electrically connected to a D-flip-flop to generate a square wave. The square wave feeds a transformer that provides a second level of isolation. The square wave is inverted by the transformer and then rectified by a full-wave bridge rectifier. The full-wave bridge rectifier outputs a DC voltage to a voltage regulator that powers the electrical circuit. A third level of isolation is provided by a second optocoupler, which outputs a signal to a level setting circuit prior to outputting the signal to an output terminal.

As a result, a cost-effective and reliable electrical circuit including optically coupled isolators and a transformer to isolate between high voltage power and low voltage programming signal lines is provided.

### BRIEF DESCRIPTION OF THE DRAWINGS

FIG. 1 is a schematic illustration of an exemplary embodiment of the invention; and

FIG. 2 is a diagram of an isolation module connected between two electrical circuits.

### DETAILED DESCRIPTION OF THE INVENTION

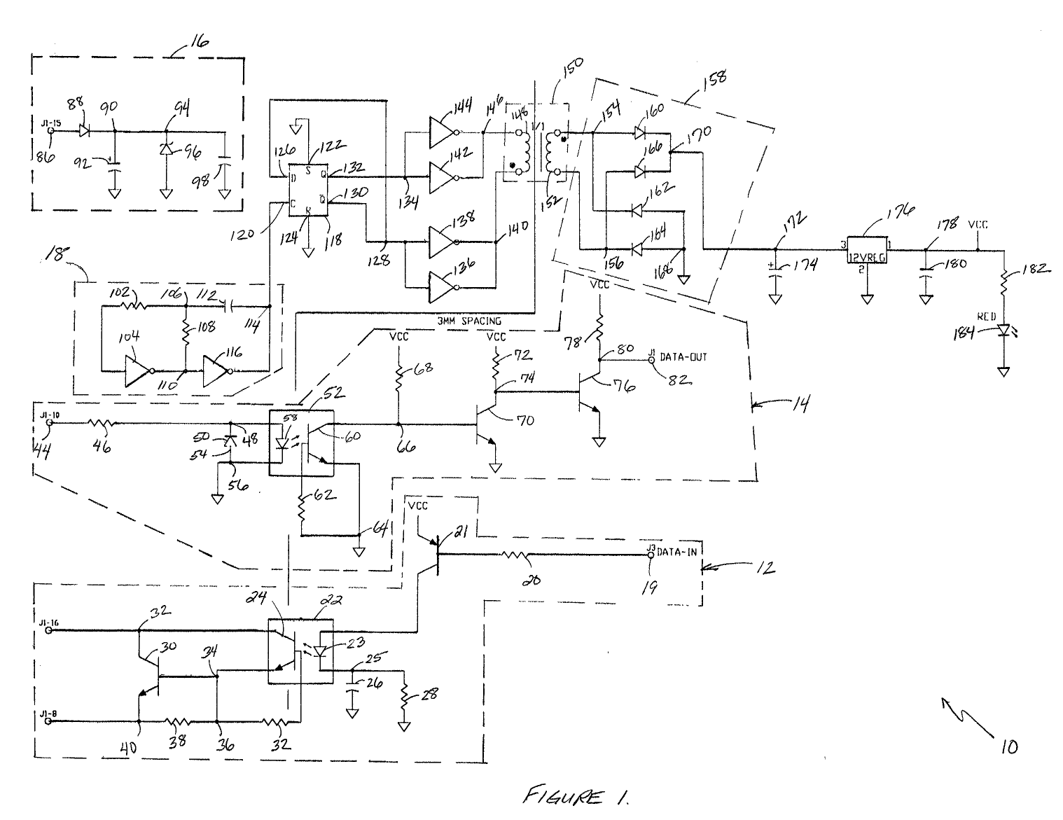

FIG. 1 is a schematic illustration of an exemplary embodiment of electrical circuit 10. Electrical circuit 10 includes a receive circuit 12, a transmit circuit 14, a filter circuit 16, an oscillator circuit 18 and a power supply circuit.

Receive circuit 12 includes an input terminal data-in 19 electrically connected in series to a resistor 20, which is connected to a base of transistor 21. The emitter of transistor 21 is connected to Vcc and a collector is connected to an optocoupler 22. Optocoupler 22 includes a light emitting diode (LED) 23 and a transistor 24. Connected to a node 25 is the anode of LED 23, a capacitor 26 and a resistor 28. LED 23 is optically connected to a transistor 24.

Transistor 24 and a transistor 30 are connected together in a Darlington configuration. A collector of transistor 24 is connected to a collector of transistor 30 at a node 32. An emitter of transistor 24 is connected to a base of transistor 30 at node 34. A base of transistor 24 is connected to a resistor 32 that is connected to a node 36. Node 36 is connected to a node 34 that is connected to a base of transistor 22. In addition, node 36 is connected to a resistor 38, which is connected to an emitter of transistor 30 at a node 40. The output of the Darlington configured transistors is taken at node 40.

Transmit circuit 14 includes a terminal input 44 that is connected in series to a resistor 46, which is connected to a node 48. Node 48 is connected to a cathode of diode 50 and to an optocoupler 52. An anode 54 of a diode 50 is tied to a node 56, which is tied to ground. Optocoupler 52 includes a light emitting diode (LED) 58 and a transistor 60. A base of transistor 60 is connected to a resistor 62, which is connected to an emitter of transistor 60 at a node 64. Node 64 is connected to ground. A collector of transistor 60 is connected to a node 66, which is tied to a pull-up resistor 68 that is connected to Vcc power. Node 66 is connected to a base of transistor 70. An emitter of transistor 70 is connected to ground and a collector is connected to a pull-up resistor 72 at a node 74. Pull-up resistor 72 is connected to Vcc power. Node 74 is connected to a base of transistor 76. An emitter of transistor 76 is connected to ground and a collector is connected to a pull-up resistor 78 at a node 80. Pull-up resistor 78 is connected to Vcc power, and a node 80 is connected to an output terminal data-out 82.

Filter network 16 includes a terminal 86. A signal is input at terminal 86 and terminal 86 is connected to a diode 88 that is connected to a node 90. Node 90 is connected to a capacitor 92 and to a node 94. Node 94 is connected to a cathode of a zener diode 96 whose anode is connected to ground, and node 94 is connected to a capacitor 98.

An oscillator 18 includes a resistor 102 connected to an inverter 104 and to a node 106. Inverter 104 is connected to a node 110. A resistor 108 is connected in between node 106 and node 110. Node 106 is connected to a capacitor 112, which is further connected to a node 114. An inverter 116 is connected to node 110 and node 114. Node 114 is connected to a D-flip-flop 118 at a clock terminal 120. D-flip-flop's 118 has a set terminal 122 and a reset terminal 124, which are both connected to ground. D-flip-flop's 118 has an input terminal 126 that is connected to a node 128, which is connected to D-flip-flop's inverted output terminal, Output-Q/130. D-flip-flop's 118 has a non-inverted output terminal, Output-Q 132, that is connected to a node 134.

Node 128 is connected to an inverter 136 and to an inverter 138. The outputs of inverters 136 and 138 are connected together at a node 140. Node 134 is connected to an inverter 142 and an inverter 144. The outputs of inverters 142 and 144 are connected together at a node 146. Node 146 is connected to a primary winding 148 of a transformer 150. Node 140 is connected to primary winding 148 of transformer 150. A secondary winding 152 of transformer 150 is connected to a node 154 and a node 156. Node 154 and node 156 are connected to a full-wave bridge rectifier 158. Full-wave bridge rectifier 158 includes a plurality of diodes 160, 162, 164 and 166. Node 154 is connected to an anode of diode 160 and a cathode of diode 162. Node 156 is connected to a cathode of diode 164 and an anode of diode 166. An anode of diode 162 and an anode of diode 164 are connected at a node 168, which is connected to ground. A cathode of diode 160 and a cathode of diode 166 are connected to a node 170.

The output of full-wave bridge rectifier 158 is taken at node 170. Node 170 is connected to a node 172. Node 172 is connected to a capacitor 174 and a voltage regulator 176. Voltage regulator 176 is connected to a node 178. Node 178 is connected to a capacitor 180, Vcc power, and a resistor 182. Resistor 182 is connected to a LED 184.

The function of receive circuit 12 and transmit circuit 14 is to provide an interface between two electrical circuits (not shown) operating at different voltages. Module 10 is connected to first electrical circuit, e.g., an electric motor (not shown), and to a second electrical circuit, e.g., a programming box (not shown). In one embodiment, the electric motor is to be programmed by the programming box. Receive circuit 12 receives a signal from the electric motor having a first voltage level, and receive circuit 12 adjusts this voltage prior to transmitting the signal to the programming box. The programming box then sends a signal having a second voltage level to module 10. Transmit circuit 14 accepts the voltage signal from the programming box and adjusts the voltage level to an operating voltage of the electric motor prior to transmitting it the electric motor. Therefore, the two electrical circuits are able to communicate even though they operate at different operating voltages.

Receive circuit 12 accepts signals from the electric motor at data-in 19 terminal. The electric motor sends a voltage signal having a first voltage level, which receive circuit 12 adjusts prior to providing the signal to the programming box. The input voltage signal is input to data-in 19 and the voltage is reduced by resistor 20. The reduced voltage is input to the base of pnp transistor 21, which is activated. When transistor 21 is activated, a current is transmitted to optocoupler 22. Optocoupler 22 includes light emitting diode (LED) 23 and transistor 24. In one embodiment, Optocoupler 22 is activated when the voltage across LED 23 is at least 1.2 volts and the forward current through LED 23 is at least 10 uA. When LED 23 is activated, an optical signal is transmitted to transistor 24. The optical signal generates a current in the base of transistor 24, which biases transistor 24 so it is turned on. When transistor 24 is on, current flows from the collector. In one embodiment, if the forward current through LED 23 is 20 mA, the resulting collector current produced in transistor 24 will be 1 mA when the voltage across the collector-to-emitter is 0.1 volts. Optocoupler 22 serves to isolate the input voltage at input terminal 19 from the remainder of circuit 10. Because transistor 24 is only activated by photons emitted by LED 23, optocoupler 22 isolates the signal at data-in 19. Optocoupler 22 has a fixed output voltage, based on the input voltage to LED 23. This output voltage is amplified by the darlington configuration of transistors 24 and 30. The amplified voltage is output from pin J1-B at node 40 to the programming box.

The programming box transmits a voltage signal at a second voltage level to transmit circuit 14. Transmit circuit 14 operates by accepting the signal from the programming box input at terminal 44 and adjusting the voltage prior to transmission to the electric motor. After accepting the signal at terminal 44, resistor 46 reduces the input voltage and diode 50 serves to maintain the voltage at node 48 at a particular level. If the voltage at node 48 exceeds the breakdown voltage of diode 50, diode 50 will short to ground to protect optocoupler 52. In one embodiment, diode 50 is a voltage reference. In an alternative embodiment, the voltage reference is at least a zener diode and a resistor divider network. Optocoupler 52 includes LED 58 and transistor 60. In one embodiment, Optocoupler 52 is activated when the voltage across LED 58 is at least 1.2 volts and the forward current through LED 58 is at least 10 uA. In an over current condition, LED 58 in optocoupler 52 will short-circuit causing input signal to be grounded. LED 58 will be activated when the voltage at node 48 exceeds its forward voltage potential. When LED 58 is activated, an optical signal is transmitted to transistor 60. The optical signal generates a current in the base of transistor 60, which biases transistor 60 so it is turned on. When transistor 60 is on, current flows from the collector. Because transistor 60 is only activated by photons emitted by LED 58, optocoupler 52 isolates the signal on terminal 44 from output terminal 82. In one embodiment, if the forward current through LED 58 is 20 mA, the resulting collector current produced in transistor 60 will be 1 mA when the voltage across the collector-to-emitter is 0.1 volts.

The output of the signal from transistor 60 is taken from its collector at node 66. In one embodiment, the signal at node 66 is inverted with respect to the signal input to transistor 60. Connected to node 66 is resistor 68, which serves to pull-up the voltage at node 66 to a value approximately at Vcc when transistor 60 is turned off. When transistor 60 is activated, the voltage at node decreases. Resistor 68 also serves to determine a threshold operating voltage at the input to optocoupler 52 and to set the response time of transistor 60.

The output signal at node 66 is input to the base of transistor 70. Transistor 70 is connected to transistor 76 in a cascaded amplifier configuration. Both transistor 70 and transistor 76 are operating as amplifiers. By connecting transistor 70 and transistor 76 together the total gain is the product of the two transistors. The cascaded amplifier configuration is a level setting circuit. The output of transistor 76 is the amplified voltage at data-out terminal 82 that is supplied to the electric motor.

Oscillator 18, configured as a hex inverter oscillator, is a clock generator. Inverters 104 and 116, resistors 102 and 108, and capacitor 112 are used to generate an oscillating square wave of a fixed frequency. The square wave has two components: a low voltage and a high voltage both of equal time duration. The low voltage part of the square wave is created when capacitor 112 charges through resistor 108. The high voltage part of the square wave is created when capacitor 112 discharges through resistor 102. The oscillating square wave of fixed frequency is input to the clock input terminal 120 of D-flip-flop 118.

D-flip-flop 118 includes an input terminal 126, a clock terminal 120, a first output-Q 132 and a second output-Q/130. Output-Q 132 and Output-Q/130 are complements of one another. Output-Q 132 and Output-Q/130 only change during a positive transition of the clock pulse input to clock terminal 120. Output-Q 132 will change to the value at input terminal 126 on a positive transition of a clock pulse. Once changed, Output-Q 132 will remain constant until another clock pulse is provided. The output of D-flip-flop 118 is a square wave.

Output-Q 132 is connected to inverters 142 and 144. Inverter 142 and inverter 144 are connected in parallel between node 134 and node 146. By connecting inverters 142 and 144 in parallel, more current is able to flow to ground, e.g., sourced to ground, when Output-Q 132 transitions from a high to a low voltage. In addition, by connecting inverters 142 and 144 in parallel, additional current is available to drive transformer 150. The output from D-flip-flop 118 output-Q 132 and output-Q/130 is a square wave. The output from output-Q 132 is opposite to the output from output-Q/130, e.g., when output-Q 132 output is a high voltage level, the output of output-Q/130 terminal is a low voltage level. The square wave is input to inverters 142 and 144 at node 134, and the inverse square wave is input to inverters 138 and 136 at node 128. The output signal from inverters 142 and 144 is “inverted” at node 146 compared to the input signal at node 134. The output signals from inverters 142 and 144 at node 146 are input to a primary winding 148 of transformer 150.

Similarly, Output-Q/130 is connected to inverters 136 and 138 at node 128. Inverter 136 and inverter 138 are connected in parallel between node 128 and node 140. By connecting inverters 136 and 138 in parallel, more current is able to flow to ground, e.g., sourced to ground, when the output of inverters 136 and 138 transitions from a high to a low voltage. In addition, by connecting inverters 136 and 138 in parallel, additional current is available to drive transformer 150. The output from D-flip-flop 118 output-Q/130 and output-Q 132 is a square wave. The output from output-Q/130 terminal is opposite to the output from output-Q 132 terminal, e.g., when output-Q/130 terminal output is a high voltage level, the output of output-Q 132 is a low voltage level. The square wave is input to inverters 136 and 138 at node 128. The output signal from inverters 136 and 138 “inverted” at node 140 compared to the input signal at node 128. The output signal from inverters 136 and 138 at node 140 are input to primary winding 148 of transformer 150.

Transformer 150 includes a primary winding 148 and a secondary winding 152. Both primary winding 148 and secondary winding 152 have the same number of turns; therefore, transformer is a 1:1 transformer. In one embodiment, transformer is not a step-up or a step-down transformer. Primary windings 148 are in the opposite direction of secondary windings 152 causing the polarity of the voltage at the terminals of secondary winding 152 to be opposite the polarity of the voltage at the terminals of the primary winding 148. Transformer 150 serves to isolate the voltage generated by oscillator 100 and the rectified DC voltage to voltage regulator 176.

The secondary winding 152 of transformer 150 is connected to a full-wave bridge rectifier 158. Full-wave bridge rectifier 158 converts the square wave to a DC voltage. The DC voltage is input to a voltage regulator 176. Capacitors 174 and capacitor 180 connected to voltage regulator 176 serve to reduce fluctuations in the DC voltage.

Full-wave bridge rectifier 158, capacitors 174 and 180, and voltage regulator 176 together regulate a dc voltage and are used as a power supply for module 10.

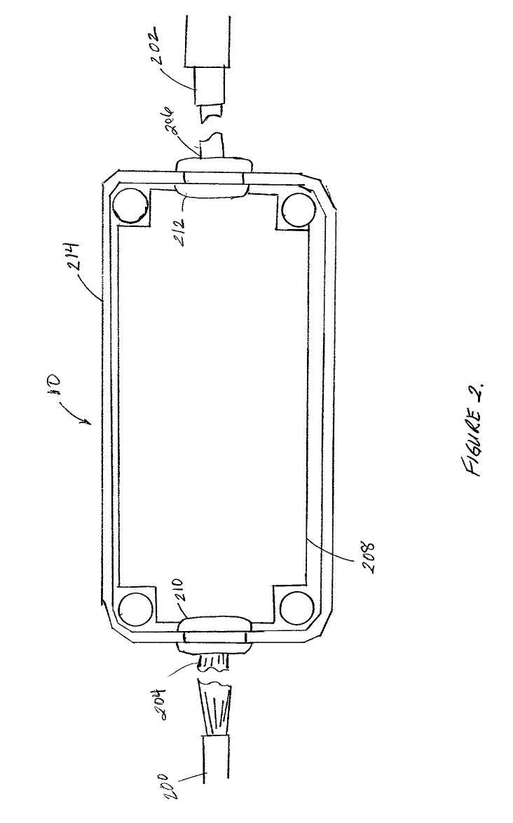

FIG. 2 is diagram is a diagram of an isolation module 10 connected between two electrical circuits (not shown). Cables 200, from a first electrical circuit, and cable 202, from a second electrical circuit, attach to input connector 204 and output connector 206 to electrically couple with module 10. Printed circuit board (PCB) 208 provides the electrical isolation between the two electrical circuits. Grommets 210 and 212 are used to reinforce connectors 204 and 206 to case 214. In one embodiment, case 214 is fabricated from plastic.

The first electrical circuit connected to cable 200 operates at a different voltage compared to the second electrical circuit connected to cable 202. Module 10 optocouplers 18 and 52 (shown in FIG. 1) electrically isolate the first electrical circuit from the second electrical circuit, and module 10 provides an interface through which the two electrical circuits can communicate. In one embodiment, the first electrical circuit is a programming box. Module 10 is configured to enable a plurality of existing programming boxes to be connected to the second electrical circuit without modification.

While the invention has been described in terms of various specific embodiments, those skilled in the art will recognize that the invention can be practiced with modification within the spirit and scope of the claims.

What is claimed is:

1. A method for isolating a programming device and a product to be programmed using an electrical circuit, the electrical circuit including an input and an output, the electrical circuit comprising a transmit circuit, a receive circuit, a first optocoupler, a second optocoupler and a transformer, the first optocoupler connected to the receive circuit and the second optocoupler connected to the transmit circuit, said method comprising the steps of:
connecting the electrical circuit to the programming device and the product to be programmed;
supplying a voltage to the electrical circuit through a transformer; and
isolating the input from the output using a plurality of optocouplers.

2. A method in accordance with claim 1 wherein said step of supplying a voltage to the electrical circuit comprising the step of generating a voltage using at least one of an oscillator, a plurality of digital logic gates, the transformer, a full-wave rectifier, and a voltage regulator.

3. A method in accordance with claim 2 wherein the transformer comprises a primary and a secondary winding, said step of isolating the oscillator voltage from the voltage regulator using the transformer's primary and secondary windings.

4. A method in accordance with claim 1 wherein said step of isolating the input from the output using a plurality of optocouplers comprises the step of isolating an input to the receive circuit using a first optocoupler.

5. A method in accordance with claim 1 wherein said step of isolating the input from the output using a plurality of optocouplers comprises the step of isolating an output of the transmit circuit using a second optocoupler.

6. An apparatus comprising an electric circuit comprising a transmit circuit, a receive circuit, a first optocoupler, a second optocoupler and a transformer, said receive circuit connected to an input and said first optocoupler and said transmit circuit connected to an output and said second optocoupler, said electrical circuit connected in series to a programming device and a product to be programmed.

7. An apparatus in accordance with claim 6 wherein said input configured to be electrically connected to a programming device.

8. An apparatus in accordance with claim 6 wherein said output configured to be electrically connected to a product to be programmed.

9. An apparatus in accordance with claim 6 wherein said receive circuit comprises said first optocoupler electrically connected to a transistor, said transistor configured in a darlington configuration.

10. An apparatus in accordance with claim 6 wherein said transmit circuit comprises said second optocoupler electrically connected to a level-setting circuit.

11. An apparatus in accordance with claim 10 wherein said level-setting circuit comprises a first and second transistor, said first and second transistors configured as cascaded amplifiers.

12. An apparatus in accordance with claim 6 wherein said transmit circuit further comprises a voltage reference, said voltage reference electrically connected to said second optocoupler's input.

13. An apparatus in accordance with claim 12 wherein said voltage reference comprises at least one of a diode, a zener diode, and a resistor divider network.

14. An apparatus in accordance with claim 6 wherein said transformer comprises a primary winding and a secondary winding, said primary winding electrically connected to a plurality of inverters.

15. An apparatus in accordance with claim 14 wherein said plurality of inverters electrically connected to a logic gate.

16. An apparatus in accordance with claim 15 wherein said logic gate electrically connected to an oscillator.

17. An apparatus in accordance with claim 16 wherein said oscillator comprises a plurality of inverters electrically connected to a plurality of resistors and a capacitor.

18. An apparatus in accordance with claim 14 wherein said transformer secondary winding electrically connected to a full-wave bridge rectifier.

19. An apparatus in accordance with claim 18 wherein said full-wave bridge rectifier electrically connected to a voltage regulator.

20. An apparatus in accordance with claim 6 wherein said circuit further comprises an electrical filter, said electrical filter comprises a plurality of capacitors electrically connected to a diode and a zener diode.

21. An electrical interface to connect a programming device to a product to be programmed, said electrical interface comprising an electric circuit comprising a transmit circuit, a receive circuit, a first optocoupler, a second optocoupler and a transformer, said receive circuit connected to an input and said first optocoupler and said transmit circuit connected to an output and said second optocoupler.

22. An electrical interface in accordance with claim 21 wherein said interface electrically isolates the input from the output using a plurality of optocouplers.

23. An electrical interface in accordance with claim 21 wherein said interface generates a supply voltage to the transmit and receive circuits using at least one of an oscillator, a plurality of digital logic gates, the transformer, a full-wave rectifier, and a voltage regulator.

24. An electrical interface in accordance with claim 21 wherein the transformer comprises a primary and a secondary winding, said transformer's primary and secondary windings isolate said oscillator voltage from said voltage regulator.

25. An electrical interface in accordance with claim 21 wherein said receive circuit configured to be electrically isolated from said transmit circuit.
